(19) United States
(12) Patent Application Publication
(10) Pub. No.: US 2024/0349492 A1
(43) Pub. Date: Oct. 17, 2024

(54) SEMICONDUCTOR MEMORY DEVICE

(71) Applicant: SAMSUNG ELECTRONICS CO., LTD., SUWON-SI (KR)

(72) Inventors: MYEONG-DONG LEE, Suwon-si (KR); SEUNG-BO KO, Suwon-si (KR); KEUNNAM KIM, Suwon-si (KR); JONGMIN KIM, Suwon-si (KR); HUI-JUNG KIM, Suwon-si (KR); TAEJIN PARK, Suwon-si (KR); DONGHYUK AHN, Suwon-si (KR); KISEOK LEE, Suwon-si (KR); MINYOUNG LEE, Suwon-si (KR); INHO CHA, Suwon-si (KR)

(21) Appl. No.: 18/543,279

(22) Filed: Dec. 18, 2023

(30) Foreign Application Priority Data
Apr. 14, 2023 (KR) 10-2023-0049364

(51) Int. Cl. H10B 12/00

(52) U.S. Cl. CPC H10B 12/485; H10B 12/02; H10B 12/315; H10B 12/34

(57) ABSTRACT

A semiconductor memory device include first and second active patterns extending in a first direction and spaced apart from each other in a second direction crossing the first direction. The first and second active patterns include a first and second edge portions spaced apart from each other in the first direction, and a center portion therebetween. Bit line node contacts are on the center portions. Bit lines are on the bit line node contacts and extend in a third direction crossing the first and second directions. The center portions of the first and second active patterns are sequentially disposed in the second direction. Each of the bit line node contacts has a first width at a level of a top surface, a second width at a level of a bottom surface, and a third width between the top and bottom surfaces less than the first and second widths.

### CROSS-REFERENCE TO RELATED APPLICATIONS

This application claims priority under 35 U.S.C. § 119 to Korean Patent Application No. 10-2023-0049364, filed on Apr. 14, 2023 in the Korean Intellectual Property Office, the disclosure of which is incorporated by reference in its entirety herein.

### 1. TECHNICAL FIELD

The present disclosure relates to a semiconductor memory device.

### 2. DISCUSSION OF RELATED ART

Semiconductor devices have become widely used in the electronics industry due to their relatively small-size, multifunctionality and cost efficient characteristics. Types of semiconductor devices include a semiconductor memory device for storing data, a semiconductor logic device for processing data, and a hybrid semiconductor device including both memory and logic elements.

With the recent trend of high speed and low power consumption of electronic devices, semiconductor devices in the electronic devices are desired to have high operating speeds and/or low operating voltages. Thus, there has been an increased demand for semiconductor devices having a high integration density. However, as the integration density of the semiconductor device increases, the electrical characteristics and production yield of the semiconductor device may be reduced. Accordingly, research is being conducted to increase the electrical characteristics and production yield of semiconductor devices.

### SUMMARY

An embodiment of the present inventive concept provides a semiconductor memory device, which can be fabricated with ease and has an increased integration density.

An embodiment of the present inventive concept provides a semiconductor memory device with increased electrical and reliability characteristics.

According to an embodiment of the present inventive concept, a semiconductor memory device includes a first active pattern and a second active pattern that extend in a first direction and are spaced apart from each other in a second direction crossing the first direction. Each of the first and second active patterns includes a first edge portion and a second edge portion that are spaced apart from each other in the first direction, and a center portion between the first and second edge portions. Bit line node contacts are on the center portions of the first and second active patterns. Bit lines are disposed on the bit line node contacts and extend in a third direction crossing the first and second directions. The center portions of the first and second active patterns are sequentially disposed in the second direction. Each of the bit line node contacts has a first width at a level of a top surface of the bit line node contacts in direct contact with the bit lines, a second width at a level of a bottom surface of the bit line node contacts in direct contact with the first and second active patterns, and a third width between the top and bottom surfaces of the bit line node contacts, the third width is less than the first and second widths.

According to an embodiment of the present inventive concept, a semiconductor memory device includes a device isolation pattern disposed in a substrate. The device isolation pattern defines a plurality of active patterns. The device isolation pattern includes first portions extending in a first direction and second portions crossing the first portions and extending in a second direction. First and second word lines cross active patterns and extend in the second direction. Bit lines are disposed on the active patterns and extend in a third direction crossing the first and second directions. Bit line node contacts are disposed between the active patterns and the bit lines. At least a portion of each of the bit line node contacts has an increasing width as a distance to the substrate decreases.

According to an embodiment of the present inventive concept, a semiconductor memory device includes a substrate comprising a first active pattern and a second active pattern that extend in a first direction and are spaced apart from each other in a second direction crossing the first direction. Each of the first and second active patterns includes two edge portions that are spaced apart from each other in the first direction, and a center portion that is interposed between the edge portions. A pair of word lines extend in the second direction to cross the first and second active patterns. A storage node pad and a storage node contact that are sequentially disposed on the edge portions. Bit lines are respectively disposed on the first and second active patterns and extend in a third direction crossing the first and second directions. A bit line spacer covers side surfaces of the bit lines. A bit line node contact is interposed between the center portion of each of the first and second active patterns and the bit line. A landing pad is on the storage node contact. A data storage pattern is on the landing pad. The center portions of the first and second active patterns are sequentially disposed in the second direction. The bit line node contact has a smallest width at a first level between a top surface of the bit line node contact and a bottom surface of the bit line node contact. A width of the bit line node contact decreases from the top surface of the bit line node contact to the first level and then increases from the first level to the bottom surface of the bit line node contact.

### BRIEF DESCRIPTION OF THE DRAWINGS

FIG. 1 is a plan view illustrating a semiconductor memory device according to an embodiment of the present inventive concept.

FIG. 2 is an enlarged plan view illustrating a portion of the semiconductor memory device of FIG. 1.

FIGS. 3A, 3B, 3C, and 3D are cross-sectional views taken along lines A-A′, B-B′, C-C′, and D-D′, respectively, of FIG. 1 according to embodiments of the present inventive concept.

FIG. 4 is a plan view illustrating a semiconductor memory device according to an embodiment of the present inventive concept.

FIGS. 5A, 5B, and 5C are cross-sectional views taken along lines A-A′, B-B′, and D-D′, respectively, of FIG. 4 according to embodiments of the present inventive concept.

FIGS. 6, 8, 10, and 12 are cross-sectional views illustrating a method of fabricating a semiconductor memory device, according to embodiments of the present inventive concept.

FIGS. 7A, 7B, 7C, and 7D are cross-sectional views taken along lines A-A′, B-B′, C-C′, and D-D′, respectively, of FIG. 6 according to embodiments of the present inventive concept.

FIGS. 9A, 9B, 9C, and 9D are cross-sectional views taken along lines A-A′, B-B′, C-C′, and D-D′, respectively, of FIG. 8 according to embodiments of the present inventive concept.

FIGS. 11A, 11B, 11C, and 11D are cross-sectional views taken along lines A-A′, B-B′, C-C′, and D-D′, respectively, of FIG. 10 according to embodiments of the present inventive concept.

FIGS. 13A, 13B, 13C, and 13D are cross-sectional views taken along lines A-A′, B-B′, C-C′, and D-D′, respectively, of FIG. 12 according to embodiments of the present inventive concept.

### DETAILED DESCRIPTION OF EMBODIMENTS

Embodiments of the present inventive concept will now be described more fully with reference to the accompanying drawings, in which non-limiting embodiments are shown.

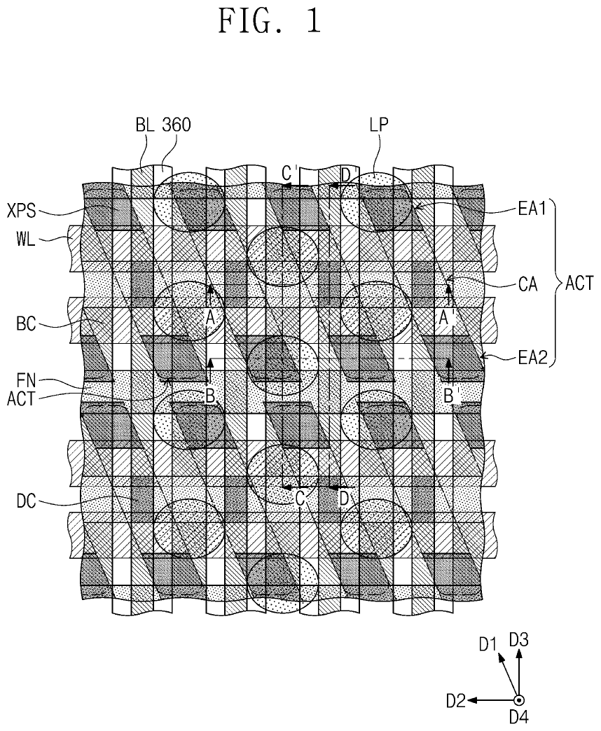

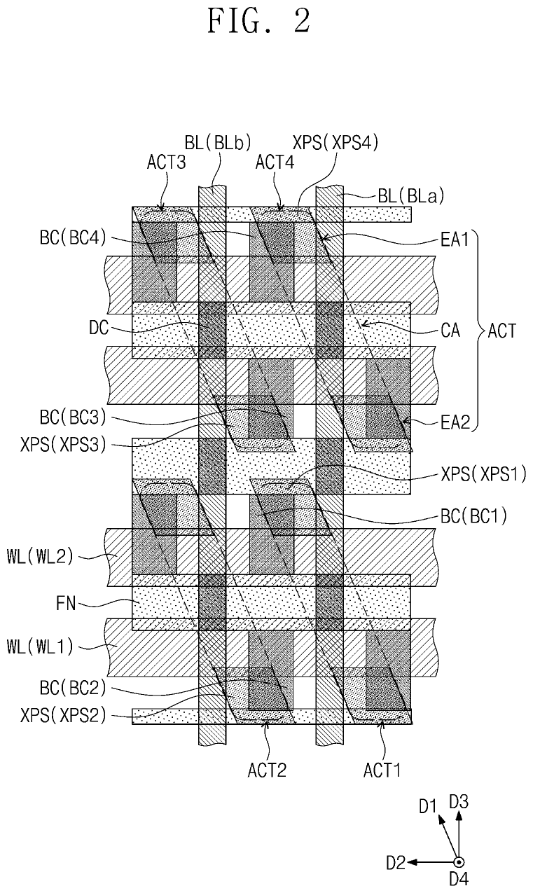

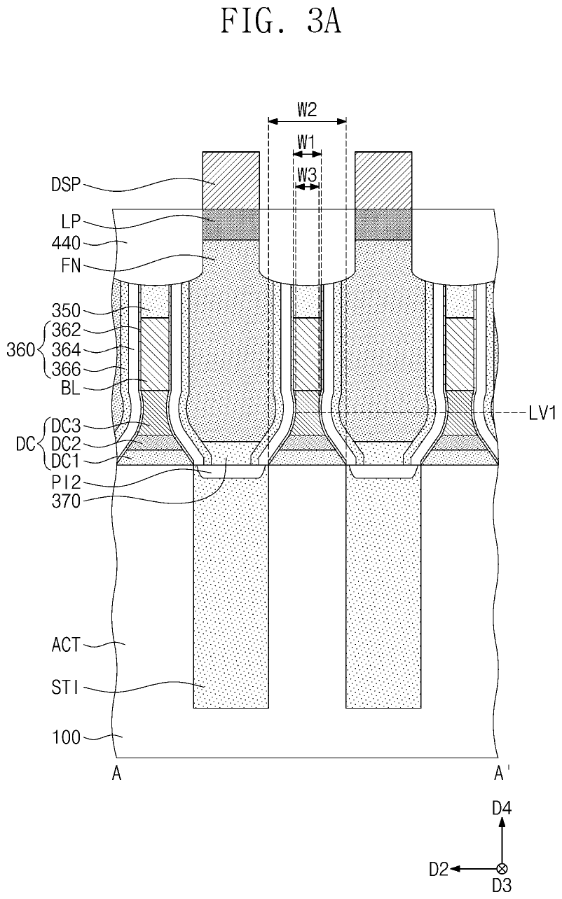

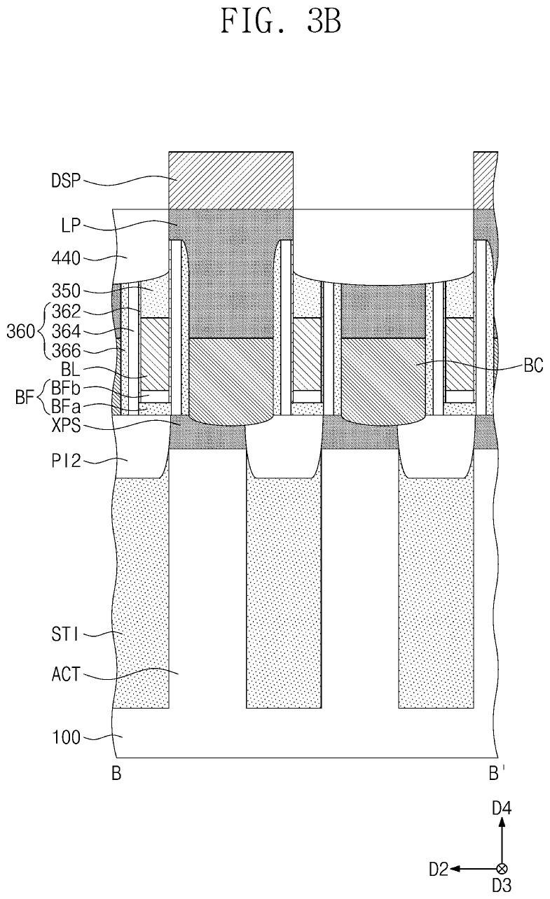

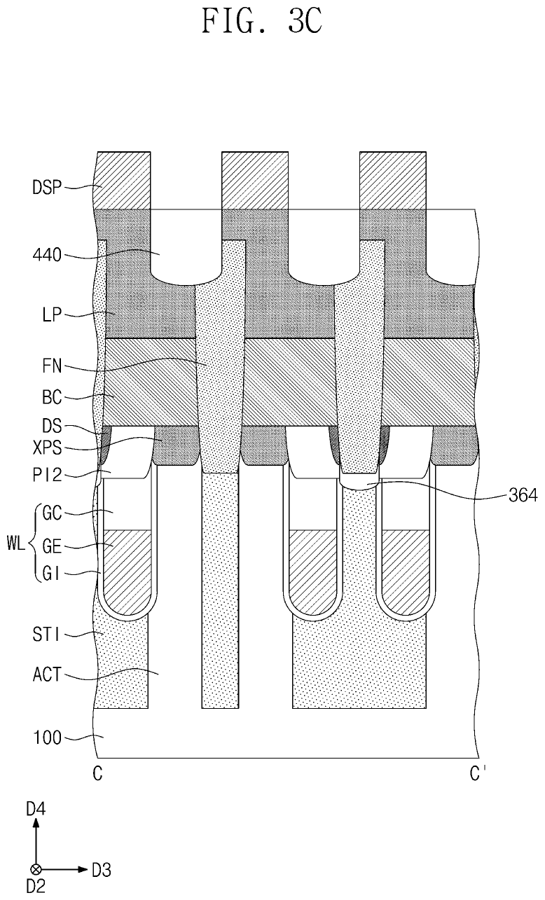

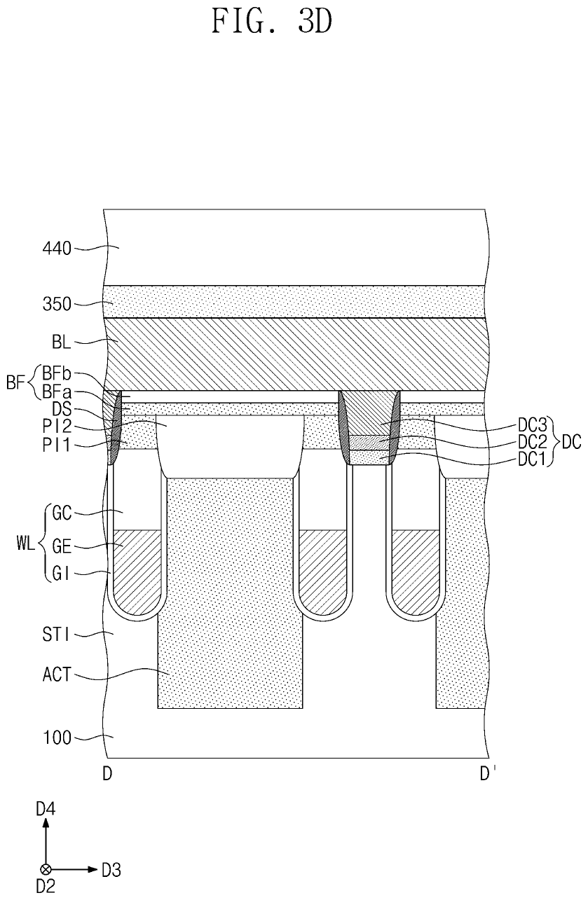

FIG. 1 is a plan view illustrating a semiconductor memory device according to an embodiment of the present inventive concept. FIG. 2 is an enlarged plan view illustrating a portion of the semiconductor memory device of FIG. 1. FIGS. 3A, 3B, 3C, and 3D are cross-sectional views taken along lines A-A′, B-B′, C-C′, and D-D′, respectively, of FIG. 1.

Referring to FIGS. 1, 2, 3A, 3B, 3C, and 3D, a substrate 100 may be provided. In an embodiment, the substrate 100 may be a semiconductor substrate, such as a silicon wafer, a germanium wafer, or a silicon-germanium wafer. However, embodiments of the present inventive concept are not necessarily limited thereto.

A device isolation pattern STI may be disposed in the substrate 100 to define an active pattern ACT. In an embodiment, a plurality of active patterns ACT may be provided. As an example, the active patterns ACT may correspond to portions of the substrate 100 enclosed by the device isolation pattern STI.

In an embodiment, each of the active patterns ACT may be a pattern that extends in a first direction D1, which is parallel to a bottom surface of the substrate 100. The active patterns ACT may be spaced apart from each other in a second direction D2 and a third direction D3, which are parallel to the bottom surface of the substrate 100 and is non-parallel to the first direction D1. The second and third directions D2 and D3 may not be parallel to each other. For example, in an embodiment, the second and third directions D2, D3 may be perpendicular to each other. However, embodiments of the present inventive concept are not necessarily limited thereto and the second and third directions D2, D3 may cross each other at various different angles. The active patterns ACT may be a pattern that extends in a fourth direction D4, which is perpendicular to the bottom surface of the substrate 100. In an embodiment, the active pattern ACT may be formed of or include silicon, such as single-crystalline silicon. However, embodiments of the present inventive concept are not necessarily limited thereto.

The active pattern ACT may include a first edge portion EA1, a second edge portion EA2 spaced apart from the first edge portion EA1 in the first direction D1, and a center portion CA between the first and second edge portions EA1 and EA2. The first and second edge portions EA1 and EA2 may be end portions of the active pattern ACT, which are opposite to each other in the first direction D1. The center portion CA may be interposed between a pair of word lines WL (e.g., in the third direction D3), which are provided to cross the active pattern ACT and will be described below. The center portions CA of the active patterns ACT may be disposed to be spaced apart from each other in the second and third directions D2 and D3. In an embodiment, the first and second edge portions EA1 and EA2 and the center portion CA may be doped with impurities, such as n-type or p-type impurities.

Adjacent ones of the active patterns ACT may be disposed side by side in at least one of the first, second, and third directions D1, D2, and D3 and opposite directions of them. For example, the center portions CA of adjacent ones of the active patterns ACT may be disposed side by side in first, second, or third direction D1, D2, or D3. In an embodiment, a first active pattern ACT1, a second active pattern ACT2, a third active pattern ACT3, and a fourth active pattern ACT4 may be disposed in a clockwise direction, as shown in FIG. 2. The first and second active patterns ACT1 and ACT2, which are adjacent to each other, may be disposed side by side in the second direction D2. For example, center portions CA of the first and second active patterns ACT1 and ACT2 may be sequentially disposed in the second direction D2. The first and third active patterns ACT1 and ACT3, which are adjacent to each other, may be disposed side by side in the first direction D1. The first and fourth active patterns ACT1 and ACT4, which are adjacent to each other, may be disposed side by side in the third direction D3. The first edge portion EA1 of the first active pattern ACT1 may be adjacent to the second edge portion EA2 of the third active pattern ACT3 in the first direction D1. The third and fourth active patterns ACT3, ACT4 may be disposed side by side in the second direction D2.

According to an embodiment of the present inventive concept, the active patterns ACT may be disposed side by side in at least one of the first, second, and third directions D1, D2, and D3 and opposite directions thereof, and in this embodiment, the elements in the semiconductor device may be disposed in a simplified manner. Thus, it may be possible to reduce a process difficulty or failure rate in a patterning process or the like, which is performed to fabricate a semiconductor memory device, and consequently, to increase the reliability characteristics of the semiconductor memory device. In addition, due to the simplified disposition of the elements, an integration density of the semiconductor memory device may be increased.

In an embodiment, the device isolation pattern STI may be formed of or include at least one of insulating materials, such as silicon oxide and silicon nitride. However, embodiments of the present inventive concept are not necessarily limited thereto. The device isolation pattern STI may be a single layer, which is formed of a single material, or a multiple layer, which is formed of two or more materials. In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements.

The word line WL may be provided to cross the active patterns ACT and the device isolation pattern STI. In an embodiment, a plurality of word lines WL may be provided. The word lines WL may extend in the second direction D2 and may be spaced apart from each other in the third direction D3. A pair of word line WL, which are spaced apart from each other in the third direction D3, may be provided to cross the active patterns ACT, which are adjacent to each other in the second direction D2. In an embodiment, a first word line WL1 and a second word line WL2 may be spaced apart from each other in the third direction D3 and may be provided to cross the first and second active patterns ACT1 and ACT2, which are adjacent to each other in the second direction D2, as shown in FIG. 2.

In an embodiment, each of the word lines WL may include a gate electrode GE, a gate dielectric pattern GI, and a gate capping pattern GC. The gate electrode GE may be arranged to penetrate the active patterns ACT and the device isolation pattern STI in the second direction D2. The gate dielectric pattern GI may be interposed between the gate electrode GE and the active patterns ACT and between the gate electrode GE and the device isolation pattern STI. The gate capping pattern GC may be disposed on the gate electrode GE to cover a top surface of the gate electrode GE. In an embodiment, the gate electrode GE may be formed of or include at least one of conductive materials. For example, in an embodiment the gate dielectric pattern GI may be formed of or include at least one of silicon oxide or high-k dielectric materials. In the present specification, the high-k dielectric material may be defined as a material having a dielectric constant higher than silicon oxide. In an embodiment, the gate capping pattern GC may be formed of or include silicon nitride.

Storage node pads XPS may be disposed on the first and second edge portions EA1 and EA2 of the active patterns ACT. The storage node pads XPS may be spaced apart from each other in the first and second directions D1 and D2. The storage node pads XPS may be electrically connected to the first and second edge portions EA1 and EA2. Each of the storage node pads XPS may be connected to a corresponding one of the first and second edge portions EA1 and EA2. For example, in an embodiment, a first storage node pad XPS1 may be connected to the first edge portion EA1 of the first active pattern ACT1. A second storage node pad XPS2 may be connected to the second edge portion EA2 of the second active pattern ACT2. A third storage node pad XPS3 may be connected to the second edge portion EA2 of the third active pattern ACT3. A fourth storage node pad XPS4 may be connected to the first edge portion EA1 of the fourth active pattern ACT4.

In an embodiment, when viewed in a plan view (e.g., in a plane defined in the second and third directions D2, D3), the storage node pad XPS may have a parallelogram shape. The storage node pad XPS may have two sides, which are extended in the first direction D1 and are opposite to each other, and other two sides, which are extended in the second direction D2 and are opposite to each other. However, embodiments of the present inventive concept are not necessarily limited thereto.

The storage node pad XPS may be formed of or include the same material as a storage node contact BC, which will be described below. As an example, the storage node pad XPS may be formed of or include silicon, such as doped polysilicon. However, embodiments of the present inventive concept are not necessarily limited thereto. For example, in an embodiment the storage node pad XPS may be formed of or include at least one of metallic materials. In an embodiment, the storage node pad XPS may have a single- or multi-layered structure.

A bit line node contact DC may be disposed on each of the active patterns ACT. In an embodiment, a plurality of bit line node contacts DC may be provided. The bit line node contacts DC may be disposed on the center portions CA of the active patterns ACT, respectively. In an embodiment, the bit line node contacts DC may be spaced apart from each other in the second and third directions D2 and D3. The bit line node contacts DC may be interposed between the active patterns ACT and bit lines BL, which will be described below. The bit line node contacts DC may electrically connect the active patterns ACT to the bit lines BL.

Each of the bit line node contacts DC may include a first portion DC1, a second portion DC2, and a third portion DC3, which are sequentially disposed on the center portions CA of the active patterns ACT (e.g., in the fourth direction D4). In an embodiment, the first portion DC1 may be in direct contact with the center portion CA of each of the active patterns ACT. The third portion DC3 may be in direct contact with the bit lines BL. The second portion DC2 may be interposed between the first portion DC1 and the third portion DC3 (e.g., in the fourth direction D4). In an embodiment, the first, second, and third portions DC1, DC2, and DC3 of the bit line node contacts DC may be formed of or include different materials each other. For example, in an embodiment the first portion DC1 may be formed of or include silicon, such as doped polysilicon. The second portion DC2 may be formed of or include at least one of metal silicide materials. The third portion DC3 may be formed of or include at least one of metallic materials. However, embodiments of the present inventive concept are not necessarily limited thereto.

When measured in the second direction D2, a top surface of each of the bit line node contacts DC may have a first width W1, and a bottom surface may have a second width W2 larger than the first width W1. The top surface of the bit line node contact DC may be in direct contact with the bit line BL, and the bottom surface of the bit line node contact DC may be in direct contact with the active pattern ACT. When measured in the second direction D2, a portion of the third portion DC3 of each of the bit line node contacts DC may have a third width W3 that is less than the first and second widths W1 and W2. In an embodiment, the third width W3 may be the smallest width of the bit line node contacts DC. As a distance to the active pattern ACT decreases, a width of the second and third portions DC2 and DC3 of each of the bit line node contacts DC in the second direction D2 may increase. For example, when measured in the second direction D2, a width of the bit line node contact DC may decrease from its top level to a first level LV1 and then increase from the first level LV1 to its bottom level, and here, the bit line node contact DC may have the third width W3 at the first level LV1.

According to an embodiment of the present inventive concept, the bit line node contacts DC may be formed through an etching process. As a result of the etching process, a portion of the bit line node contact DC between the top and bottom surfaces of the bit line node contact DC may be over-etched to have the third width W3 that is less than the first and second widths W1 and W2 of the top and bottom surfaces of the bit line node contact DC. Since the bit line node contact DC includes a metal-containing portion, it may be possible to suppress the over-etching issue, compared with an embodiment in which the entirety of the bit line node contact DC is formed only of polysilicon. Thus, the reliability characteristics of the semiconductor memory device may be increased.

A first pad insulating pattern PI1 and a second pad insulating pattern PI2 may be arranged to enclose side surfaces of the storage node pads XPS and side surfaces of the bit line node contacts DC. The first and second pad insulating patterns PI1 and PI2 may electrically separate the storage node pads XPS and the bit line node contacts DC from each other. Each of the first and second pad insulating patterns PI1 and PI2 may be formed of or include at least one insulating material.

A bit line node contact spacer DS may be arranged on a side surface of the bit line node contact DC. As an example, the bit line node contact spacer DS may cover a side surface of the bit line node contact DC in the third direction D3 (or the opposite direction thereof). The bit line node contact spacer DS may be interposed between the bit line node contact DC and the first pad insulating pattern PI1, which are adjacent to each other in the third direction D3 (or the opposite direction thereof).

The bit line BL may be disposed on the bit line node contact DC. The bit line BL may extend in the third direction D3. In an embodiment, a plurality of bit lines BL may be provided and may be spaced apart from each other in the second direction D2. In an embodiment, the bit line BL may be formed of or include at least one of metallic materials. As an example, the bit line BL may be formed of or include at least one of tungsten, rubidium, molybdenum, or titanium. As another example, the bit line BL may further include at least one of metal silicide materials or metal nitride materials. However, embodiments of the present inventive concept are not necessarily limited thereto.

The bit line BL may be disposed on the center portions CA of the active patterns ACT, which are disposed side by side in the third direction D3 to form one column, and may be electrically connected to the column of the active patterns ACT through the bit line node contacts DC. For example, a first bit line BLa may be disposed on and electrically connected to the center portions CA of the first and fourth active patterns ACT1 and ACT4, which are disposed side by side in the third direction D3. A second bit line BLb may be disposed on and electrically connected to the center portions CA of the second and third active patterns ACT2 and ACT3, which are disposed side by side in the third direction D3.

A buffer pattern BF may be disposed below the bit line BL to cover the substrate 100. The buffer pattern BF may be interposed between two bit line spacers 360, which are positioned between the bit line BL and the first pad insulating pattern PI1 and between the bit line BL and the second pad insulating pattern PI2 to cover opposite side surfaces (e.g., in the second direction D2) of one bit line BL. The buffer pattern BF may be interposed between the bit line node contacts DC, which are adjacent to each other in the third direction D3. In an embodiment, the buffer pattern BF may be formed of or include at least one compound selected from silicon oxide, silicon nitride, silicon oxynitride, and high-k dielectric materials. The buffer pattern BF may be a single layer, which is formed of a single material, or a multiple layer, which is formed of two or more materials. In an embodiment, the buffer pattern BF may be a multiple layer including a lower buffer pattern BFa and an upper buffer pattern BFb.

A bit line capping pattern 350 may be disposed on a top surface of the bit line BL. The bit line capping pattern 350, along with the bit line BL, may extend in the third direction D3. In an embodiment, a plurality of bit line capping patterns 350 may be provided. The bit line capping patterns 350 may be spaced apart from each other in the second direction D2. The bit line capping pattern 350 may vertically overlap the bit line BL (e.g., in the fourth direction D4). The bit line capping pattern 350 may be composed of a single layer or a plurality of layers. For example, in an embodiment, the bit line capping pattern 350 may be formed of or include silicon nitride. However, embodiments of the present inventive concept are not necessarily limited thereto.

The bit line spacer 360 may be disposed on a side surface (e.g., a lateral side surface) of the bit line BL, a side surface of the bit line capping pattern 350, and a side surface of the bit line node contact DC. The bit line spacer 360 may cover (e.g., completely cover) the side surface of the bit line BL, the side surface of the bit line capping pattern 350, and the side surface of the bit line node contact DC. The bit line spacer 360 may be extended in the third direction D3, on the side surface of the bit line BL, the side surface of the bit line capping pattern 350, and the side surface of the bit line node contact DC.

The bit line spacer 360 may include a plurality of spacers. In an embodiment, the bit line spacer 360 may include a first spacer 362, a second spacer 364, and a third spacer 366. As shown in an embodiment of FIG. 3A, the first spacer 362 may be in direct contact with the side surface of the bit line BL, the side surface of the bit line capping pattern 350, and the side surface of the bit line node contact DC. The third spacer 366 may be disposed adjacent to the storage node contact BC, which will be described below. The second spacer 364 may be interposed between the first spacer 362 and the third spacer 366. In an embodiment, each of the first to third spacers 362, 364, and 366 may be independently formed of or include at least one of silicon nitride, silicon oxide, or silicon oxynitride. However, embodiments of the present inventive concept are not necessarily limited thereto.

Filling patterns 370 may be disposed on the substrate 100 and arranged between the bit line spacer 360, which are adjacent to each other in the second direction D2. In an embodiment, a top surface of each of the filling patterns 370 may be located at a vertical level (e.g., level in the fourth direction D4) that is lower than a top surface of the bit line node contact DC. In an embodiment, the filling patterns 370 may be spaced apart from each other in the second and third directions D2 and D3. The filling patterns 370 may be formed of or include an insulating material (e.g., silicon nitride). However, embodiments of the present inventive concept are not necessarily limited thereto.

The storage node contact BC may be arranged between the bit lines BL, which are adjacent to each other in the second direction D2. The storage node contact BC may be interposed between the bit line spacers 360, which are adjacent to each other in the second direction D2. In an embodiment, a plurality of storage node contacts BC may be provided. In an embodiment, the storage node contacts BC may be spaced apart from each other in the second and third directions D2 and D3. Adjacent ones of the storage node contacts BC may be arranged in the second or third direction D2 or D3. The storage node contacts BC may be disposed on (e.g., disposed directly thereon in the fourth direction D4) the storage node pads XPS. The storage node contacts BC may also be disposed on the first and second edge portions EA1, EA2 of the active patterns ACT. The storage node contacts BC may be electrically connected to the first and second edge portions EA1 and EA2 of the active patterns ACT through the storage node pads XPS. For example, a first storage node contact BC1 may be connected to the first edge portion EA1 of the first active pattern ACT1 through the first storage node pad XPS1. A second storage node contact BC2 may be connected to the second edge portion EA2 of the second active pattern ACT2 through the second storage node pad XPS2. A third storage node contact BC3 may be connected to the second edge portion EA2 of the third active pattern ACT3 through the third storage node pad XPS3. A fourth storage node contact BC4 may be connected to the first edge portion EA1 of the fourth active pattern ACT4 through the fourth storage node pad XPS4.

Each of the first to fourth storage node contacts BC1, BC2, BC3, and BC4 may be interposed between the first bit line BLa and the second bit line BLb (e.g., in the section direction D2). The first to fourth storage node contacts BC1, BC2, BC3, and BC4 may be disposed to form a column in the third direction D3. In an embodiment, the second storage node contact BC2, the first storage node contact BC1, the third storage node contact BC3, and the fourth storage node contact BC4 may be sequentially arranged in the third direction D3 to form a column. In an embodiment, the storage node contact BC may be formed of or include silicon, such as doped polysilicon. However, embodiments of the present inventive concept are not necessarily limited thereto.

According to an embodiment of the present inventive concept, since the storage node pads XPS are disposed in the semiconductor memory device, the storage node contact BC may be electrically and easily connected to a corresponding one of the first and second edge portions EA1 and EA2. In an embodiment, even when the storage node contact BC is misaligned such that it is not vertically overlapped with a corresponding edge portion (e.g., in the fourth direction D4), the storage node contact BC may be electrically connected to the corresponding edge portion through the storage node pad XPS. In a comparative embodiment in which the storage node contact BC is directly in contact with and connected to a corresponding edge portion, a contact resistance may be increased due to misalignment therebetween. The storage node pad XPS may prevent a contact resistance between the storage node contact BC and the corresponding edge portion from being increased.

A fence pattern FN may be disposed between the bit lines BL, which are adjacent to each other (e.g., in the second direction D2), and between the storage node contacts BC, which are adjacent to each other in the third direction D3. The fence pattern FN may be arranged to separate the storage node contacts BC, which are adjacent to each other in the third direction D3, from each other and may be in direct contact with the adjacent ones of the storage node contacts BC. In an embodiment, a plurality of fence patterns FN may be provided. The fence patterns FN may be spaced apart from each other in the third direction D3. The fence pattern FN may include lower portions, which are extended in the fourth direction D4 between the bit lines BL and are disposed to form a row parallel to the second direction D2, and an upper portion, which is positioned at a level higher than the bit lines BL and is connected to the lower portions of the fence patterns PN to form a single object therewith. In an embodiment, an insulating pattern 440 may be arranged to penetrate the upper portion of the fence pattern FN in the fourth direction D4, as will be described below. In an embodiment, the fence pattern FN may be formed of or include silicon nitride. However, embodiments of the present inventive concept are not necessarily limited thereto.

A landing pad LP may be disposed on the storage node contact BC. In an embodiment, a plurality of landing pads LP may be provided. The landing pads LP may be spaced apart from each other in the second and third directions D2 and D3. The landing pad LP may be connected to a corresponding one of the first and second edge portions EA1 and EA2 through a corresponding one of the storage node contacts BC and a corresponding one of the storage node pads XPS.

The landing pad LP may include a lower portion and an upper portion. The lower portion of the landing pad LP may be vertically overlapped with the storage node contact BC (e.g., in the fourth direction D4). A lower portion of the landing pad may also contact (e.g., directly contact) an upper portion of the fence pattern FN. The upper portion of the landing pad LP may be shifted from (e.g., offset from) the lower portion in the third direction D3 or its opposite direction. As an example, in an embodiment the lower and upper portions of the landing pad LP may be formed of or include the same material. As another example, the lower and upper portions of the landing pad LP may be formed of or include different materials from each other. The landing pad LP may be formed of or include at least one of metallic materials (e.g., tungsten, titanium, and tantalum) or metal compounds containing tungsten, titanium, and tantalum. However, embodiments of the present inventive concept are not necessarily limited thereto.

The insulating pattern 440 may be arranged to enclose the landing pad LP. The insulating pattern 440 may be interposed between adjacent ones of the landing pads LP. When viewed in a plan view, the insulating pattern 440 may be arranged in a mesh shape with holes, and in this embodiment the landing pads LP may be disposed in the holes to penetrate the insulating pattern 440. In an embodiment, the insulating pattern 440 may be formed of or include at least one compound selected from silicon nitride, silicon oxide, and silicon oxynitride. However, embodiments of the present inventive concept are not necessarily limited thereto. For example, in an embodiment the insulating pattern 440 may include an empty space with an air layer, such as an air gap.

A data storage pattern DSP may be disposed on the landing pad LP (e.g., disposed directly thereon in the fourth direction D4). In an embodiment, a plurality of data storage patterns DSP may be provided. In an embodiment, the data storage patterns DSP may be spaced apart from each other in the second and third directions D2 and D3. Each of the data storage patterns DSP may be electrically connected to a corresponding one of the first and second edge portions EA1 and EA2 through a corresponding one of the landing pads LP, a corresponding one of the storage node contacts BC, and a corresponding one of the storage node pads XPS.

In an embodiment, the data storage pattern DSP may be a capacitor including a bottom electrode, a dielectric layer, and a top electrode. In this embodiment, the semiconductor memory device may be a dynamic random access memory (DRAM) device. In an embodiment, the data storage pattern DSP may include a magnetic tunnel junction pattern. In this embodiment, the semiconductor memory device may be a magnetic random access memory (MRAM) device. In an embodiment, the data storage pattern DSP may be formed of or include a phase-change material or a variable resistance material. In this embodiment, the semiconductor memory device may be a phase-change random access memory (PRAM) device or a resistive random access memory (ReRAM) device. However, embodiments of the present inventive concept are not necessarily limited to these examples, and the data storage pattern DSP may include various structures and/or materials which can be used to store data.

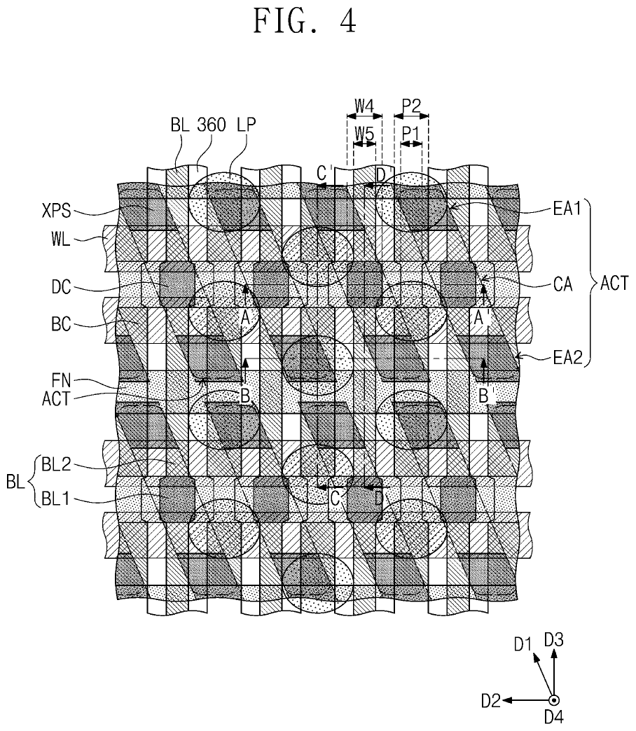

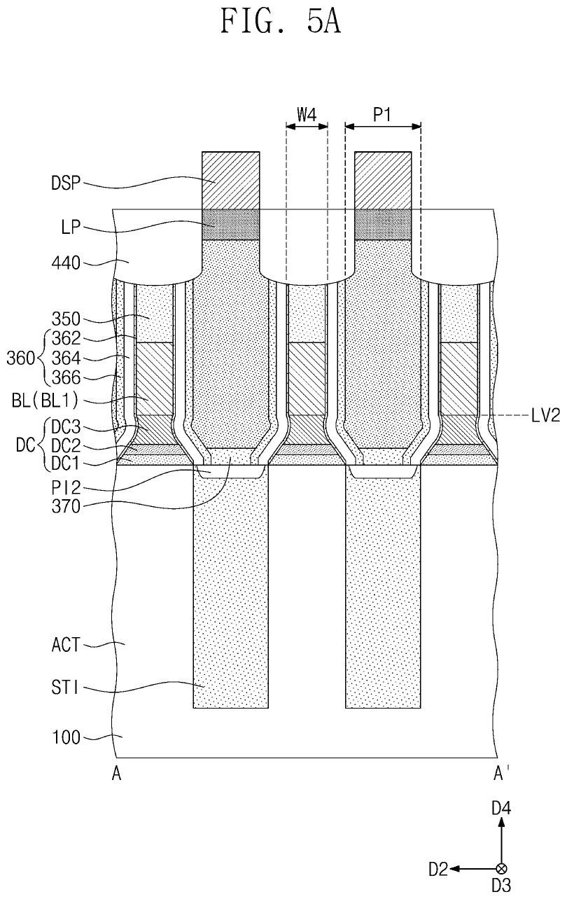

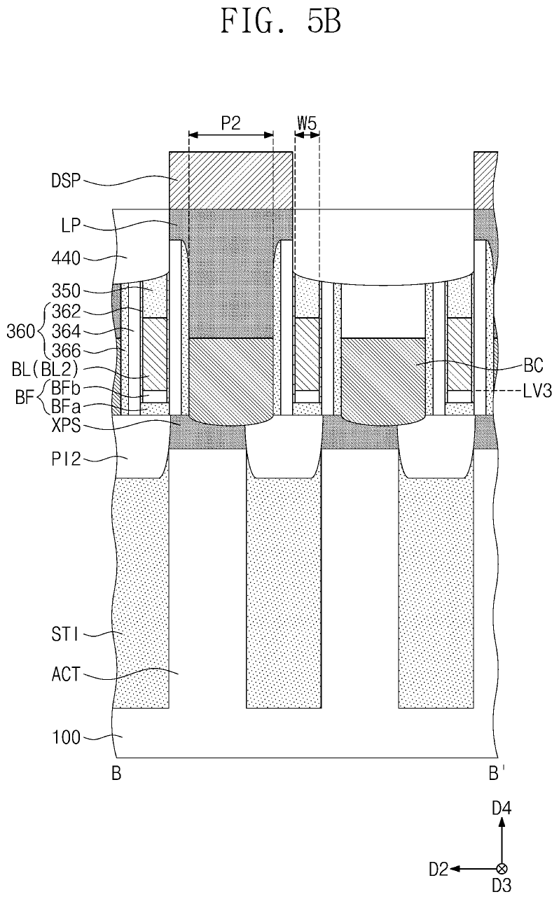

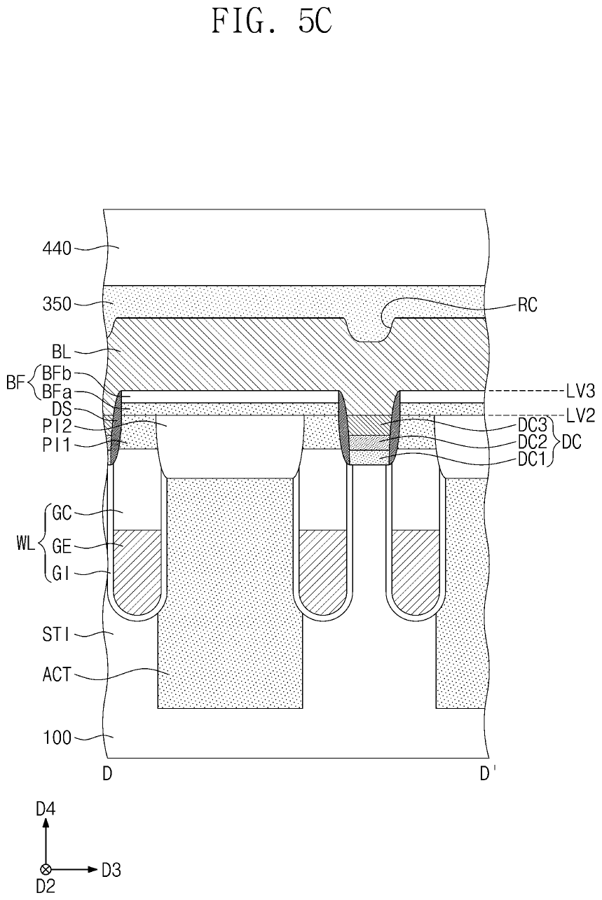

FIG. 4 is a plan view illustrating a semiconductor memory device according to an embodiment of the present inventive concept. FIGS. 5A, 5B, and 5C are cross-sectional views taken along lines A-A′, B-B′, and D-D′, respectively, of FIG. 4. In an embodiment, the cross-sectional view, which is taken along the line C-C′ of FIG. 4, may be the same as that of FIG. 3C. In the following description, an element previously described above may be identified by the same reference number without repeating an overlapping description thereof.

Referring to FIGS. 4, 5A, 5B, and 5C, the bit line node contacts DC may be disposed between the center portions CA of the active patterns ACT and the bit lines BL. In an embodiment, the bit line node contacts DC may have top surfaces which are positioned at a second level LV2, and the buffer pattern BF may have a top surface, which is positioned at a third level LV3 higher than the second level LV2. For example, the top surfaces of the bit line node contacts DC may be closer to the substrate 100 (e.g., in the fourth direction D4) than the top surface of the buffer pattern BF.

Each of the bit lines BL may include first portions BL1, which vertically overlap the bit line node contacts DC, and second portions BL2, which are formed between the first portions BL1 that are adjacent to each other in the third direction D3. The second portions BL2 of the bit lines BL may vertically overlap with the buffer pattern BF. The first portions BL1 of the bit lines BL may be provided to fill a space, which is provided on the top surfaces of the bit line node contacts DC and is arranged between the buffer patterns BF that are spaced apart from each other in the third direction D3. Thus, the bit lines BL may have recesses RC, which are recessed toward the bit line node contacts DC in regions that vertically overlap (e.g., in the fourth direction D4) the bit line node contacts DC. The bit line capping patterns 350 may cover the top surfaces of the bit lines BL and may fill the recesses RC of the bit lines BL.

When measured in the second direction D2, a fourth width W4 of the first portions BL1 of the bit lines BL may be larger than a fifth width W5 of the second portions BL2. Thus, when measured in the second direction D2, a first distance P1 between the bit line spacer 360 on adjacent ones of the first portions BL1 may be less than a second distance P2 between the bit line spacer 360 on adjacent ones of the second portions BL2.

According to an embodiment of the present inventive concept, the first portions BL1 of the bit lines BL, which are overlapped with the bit line node contact DC, may be positioned at a vertical level that is lower than the second portions BL2 of the bit lines BL, which are not overlapped with the bit line node contact DC, and in this embodiment, the first portions BL1 may be less influenced by an etching process when forming the bit lines BL and the bit line node contact DC in the fabrication process. Thus, since the fourth width W4 of the first portions BL1 of the bit lines BL is larger than the fifth width W5 of the second portions BL2, the first portions BL1 of the bit lines BL may be electrically connected to the bit line node contacts DC and the active patterns ACT, which are adjacent thereto, with an increased connection area. In addition, as the fifth width W5 of the second portion BL2 of the bit line BL decreases, the second distance P2, which is a distance between the bit line spacers 360 on the second portion BL2 of the bit line BL, may increase. This may increase an area for an electric connection between the active patterns ACT and the storage node contact BC.

In addition, since the bit lines BL include the recesses RC, it may be possible to reduce a facing area between the bit lines BL, which are adjacent to each other in the second direction D2. Accordingly, it may be possible to reduce a coupling capacitance between adjacent ones of the bit lines BL and thereby to realize a semiconductor memory device with increased reliability.

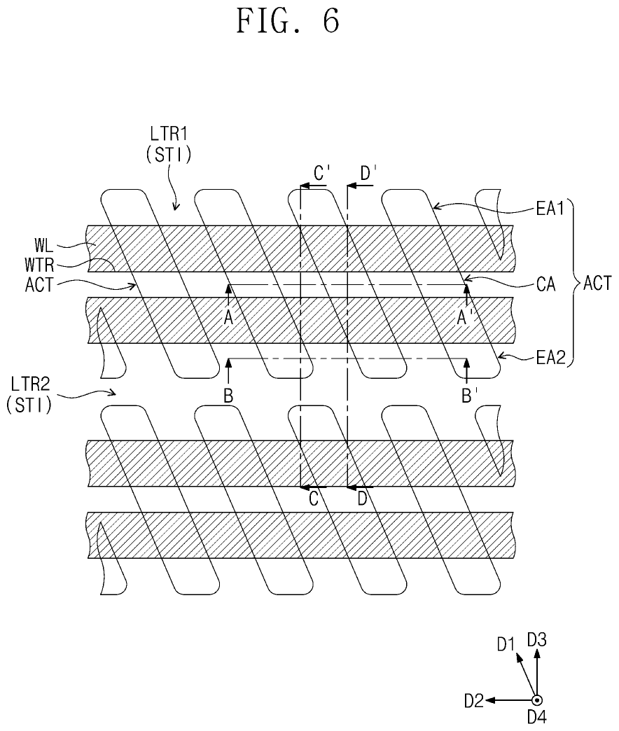

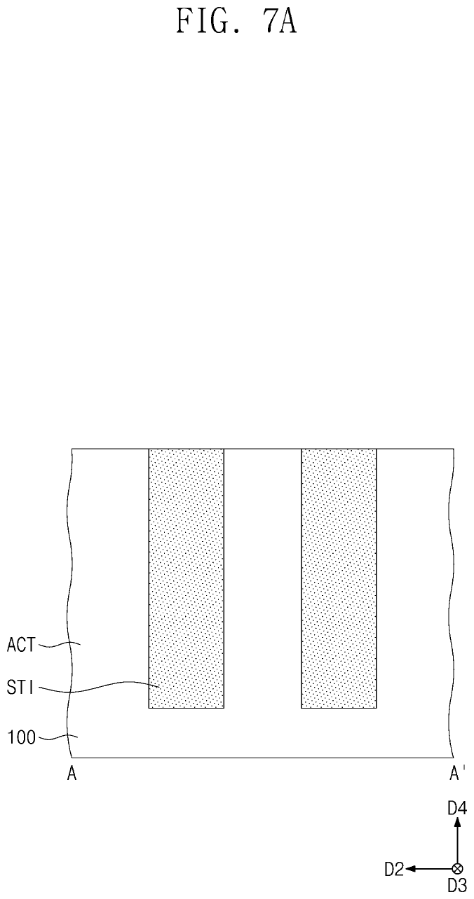

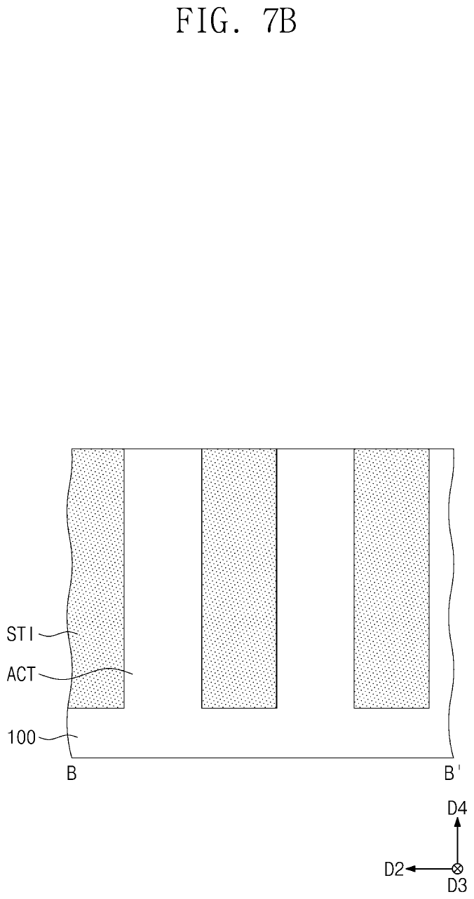

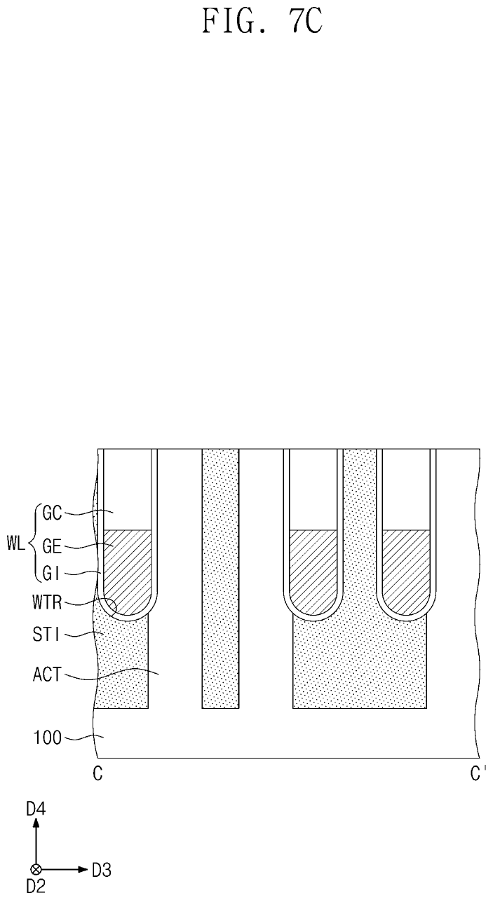

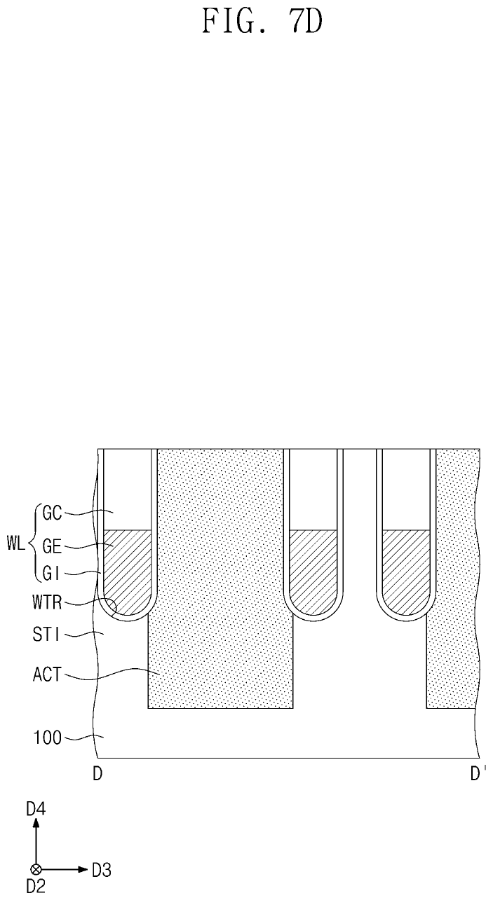

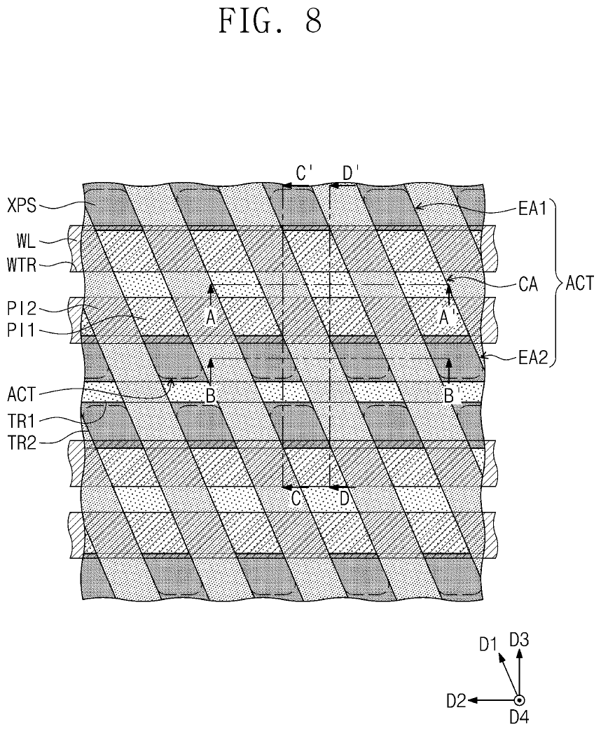

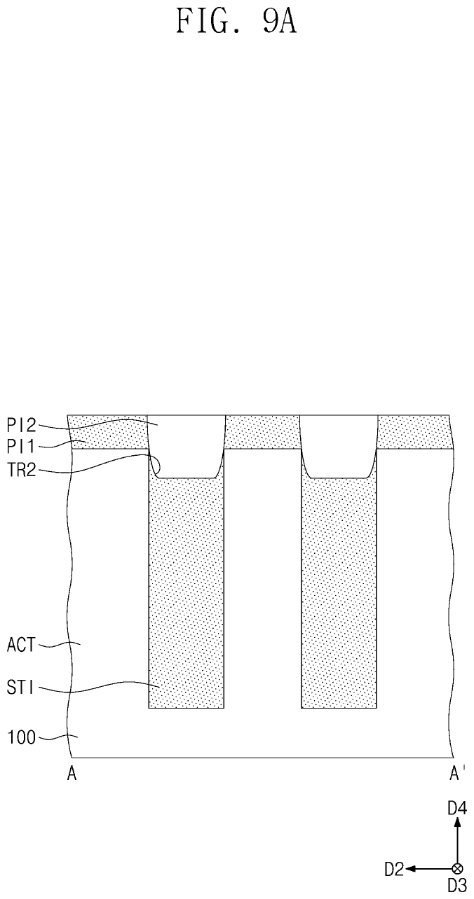

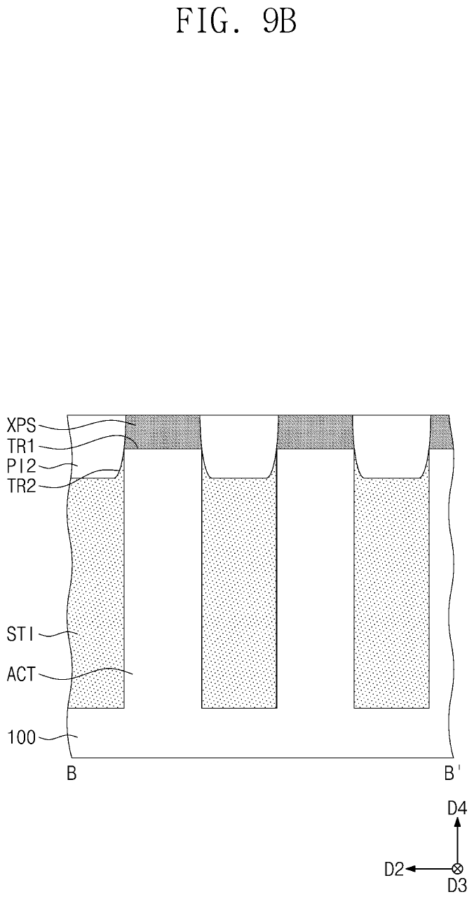

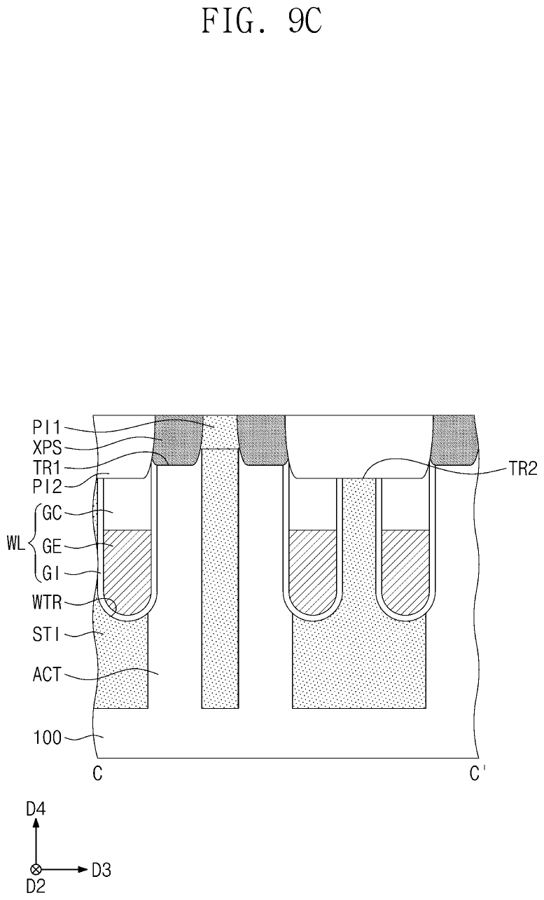

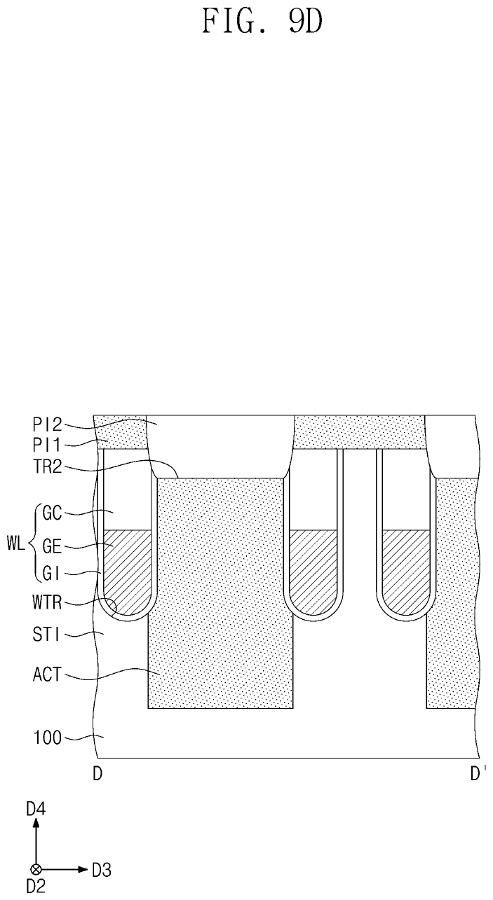

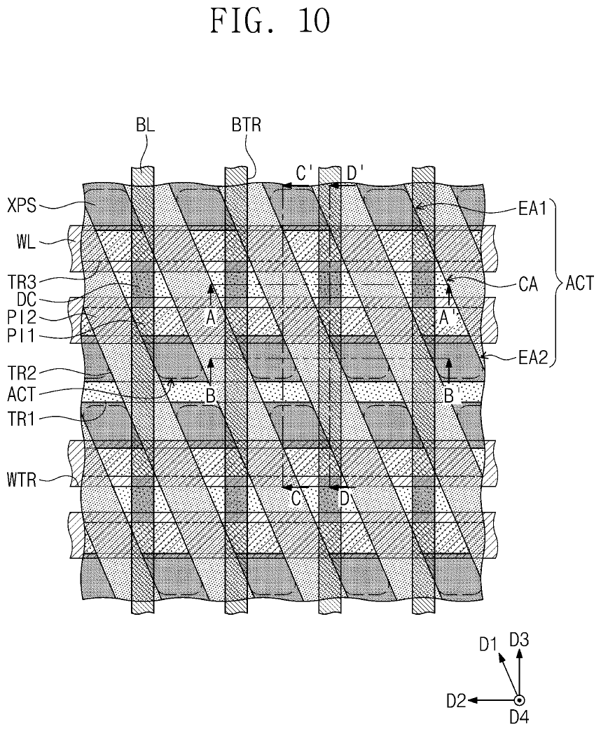

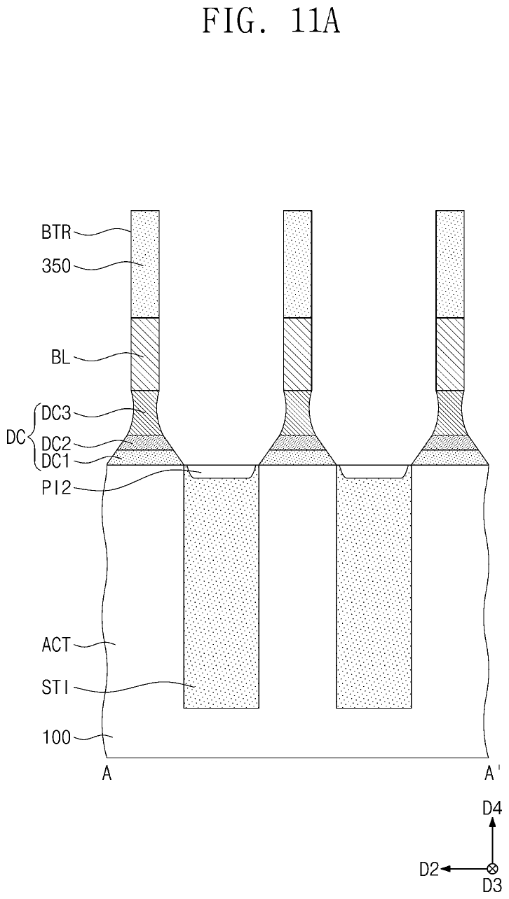

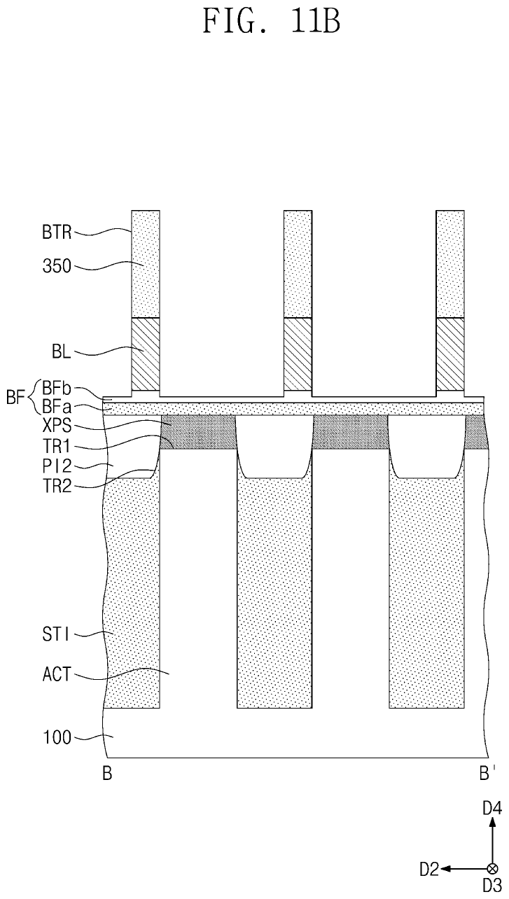

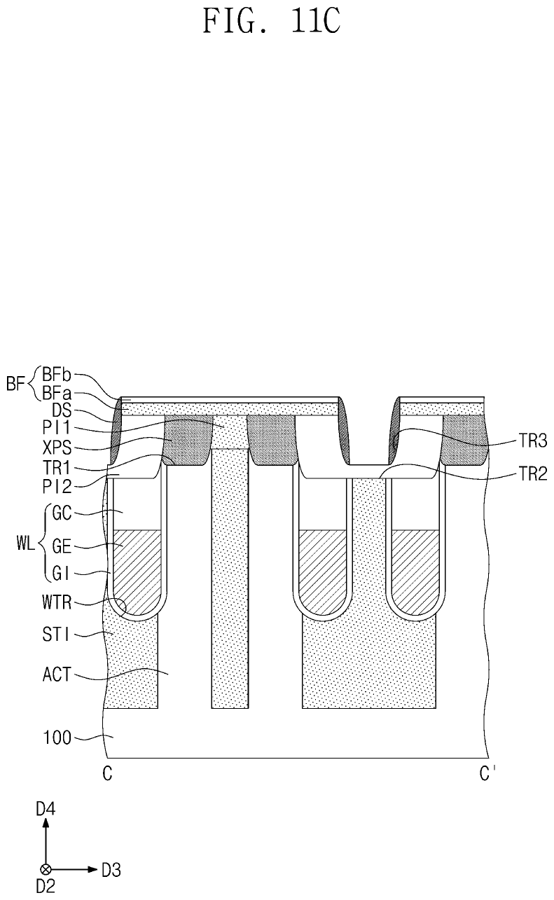

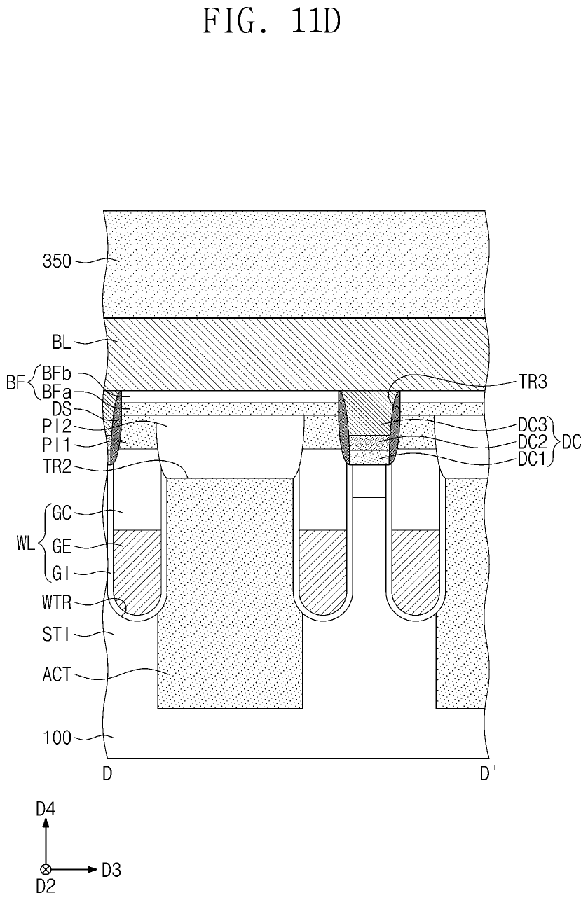

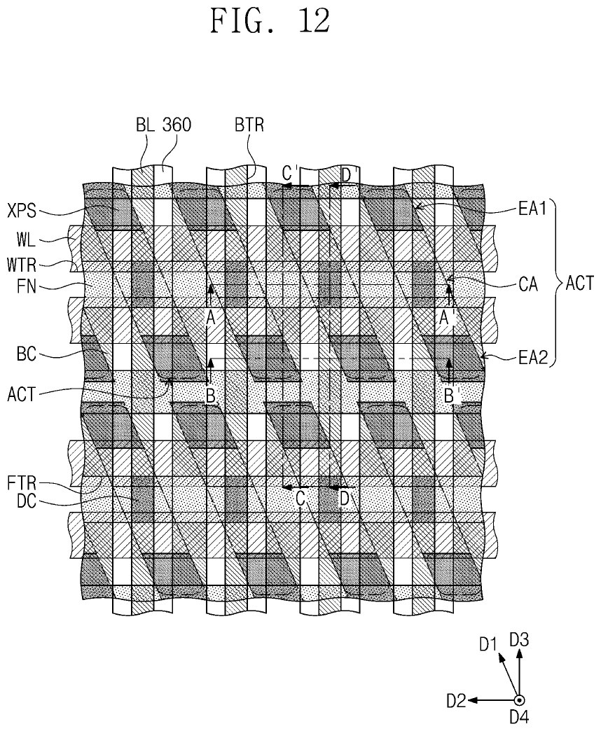

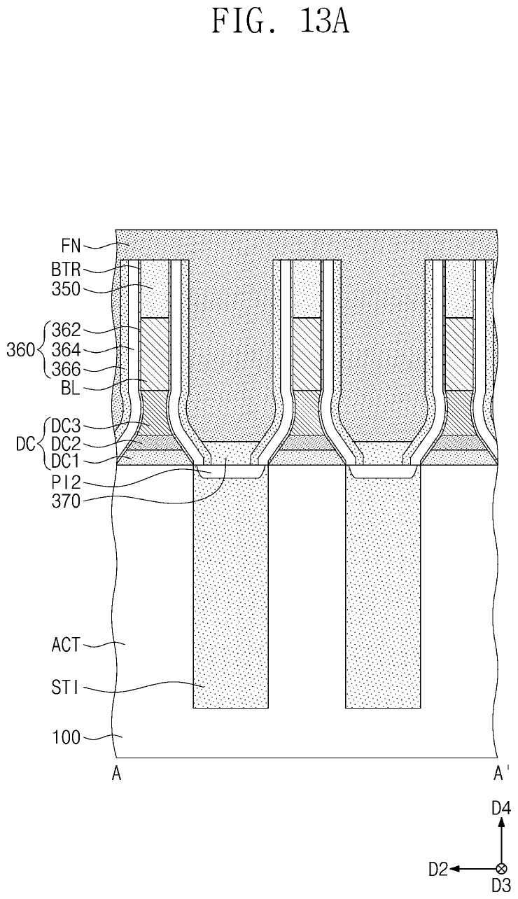

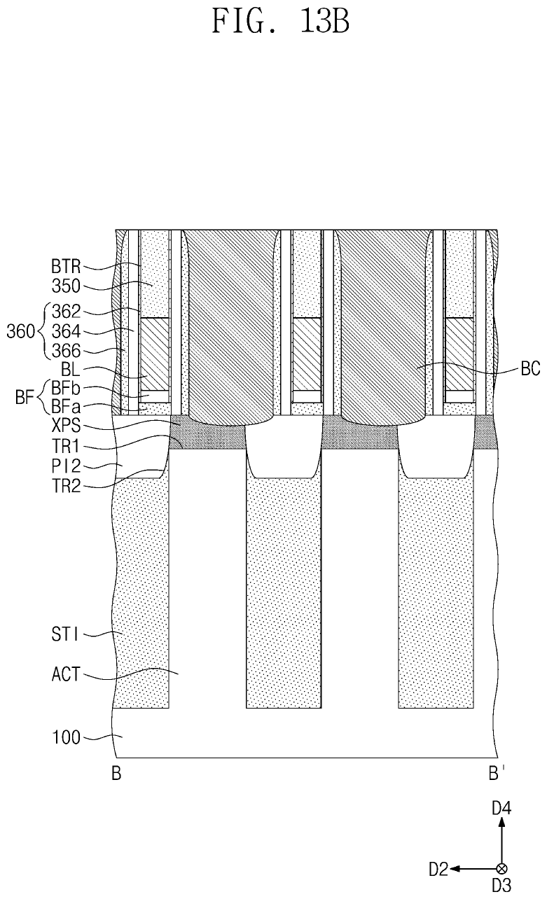

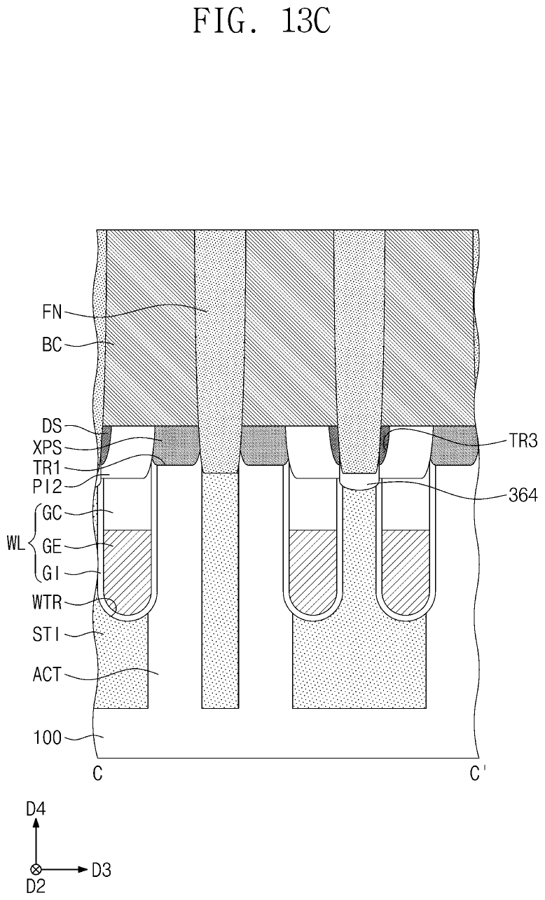

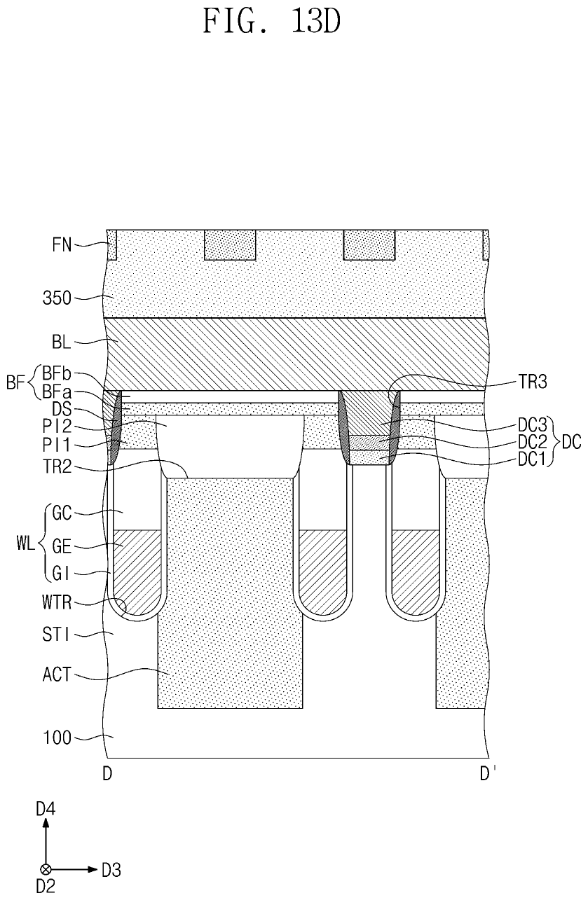

FIGS. 6, 8, 10, and 12 are cross-sectional views illustrating a method of fabricating a semiconductor memory device, according to embodiments of the present inventive concept. FIGS. 7A, 7B, 7C, and 7D are cross-sectional views taken along lines A-A′, B-B′, C-C′, and D-D′ of FIG. 6. FIGS. 9A, 9B, 9C, and 9D are cross-sectional views taken along lines A-A′, B-B′, C-C′, and D-D′ of FIG. 8. FIGS. 11A, 11B, 11C, and 11D are cross-sectional views taken along lines A-A′, B-B′, C-C′, and D-D′ of FIG. 10. FIGS. 13A, 13B, 13C, and 13D are cross-sectional views taken along lines A-A′, B-B′, C-C′, and D-D′ of FIG. 12.

Referring to FIGS. 6, 7A, 7B, 7C, and 7D, the substrate 100 may be prepared. A removal process may be performed on the substrate 100 to form the active patterns ACT. The removal process may include performing an exposing process to form mask patterns on the substrate 100 and etching the substrate 100 using the mask patterns as an etch mask. The exposing process and the etching process may be alternatively repeated several times. For example, a first exposing/etching process may be performed to form line patterns and first line trench regions LTR1, which are extended in the first direction D1. Thereafter, a second exposing/etching process may be performed on the line patterns. The second exposure/etching process may be performed to form second line trench regions LTR2, which are extended in the second direction D2, and each of the line patterns may be divided into the active patterns ACT, which are linearly arranged in the first direction D1.

The device isolation pattern STI may be formed to fill the first and second line trench regions LTR1 and LTR2. In an embodiment, the formation of the device isolation pattern STI may include performing a physical vapor deposition (PVD) process, a chemical vapor deposition (CVD) process, or an atomic layer deposition (ALD) process. However, embodiments of the present inventive concept are not necessarily limited thereto.

Thereafter, the word line WL may be formed to cross the active pattern ACT and the device isolation pattern STI. The formation of the word line WL may include forming a mask pattern on the active pattern ACT and the device isolation pattern STI, performing an anisotropic etching process using the mask pattern to form a word line trench region WTR, and filling the word line trench region WTR with the word line WL.

In an embodiment, the filling of the word line WL may include conformally depositing the gate dielectric pattern GI on an inner surface of the word line trench region WTR, filling the word line trench region WTR, in which the gate dielectric pattern GI is formed, with a conductive layer, performing an etch-back and/or polishing process on the conductive layer to form the gate electrode GE, and forming the gate capping pattern GC on the gate electrode GE to fill a remaining portion of the word line trench region WTR.

Referring to FIGS. 8, 9A, 9B, 9C, and 9D, the first pad insulating pattern PI1 may be formed on the active pattern ACT and the device isolation pattern STI. In an embodiment, the formation of the first pad insulating pattern PI1 may include forming a first pad insulating layer on the substrate 100 and performing an anisotropic etching process on the first pad insulating layer to form first pad insulating patterns PI1 and first trench regions TR1. The first pad insulating patterns PI1 and the first trench regions TR1 may extend in the second direction D2. The first and second edge portions EA1 and EA2 of the active pattern ACT may be exposed through the first trench regions TR1.

In an embodiment, preliminary pad patterns may be formed to fill the first trench regions TR1. The preliminary pad pattern in the first trench regions TR1 may extend in the second direction D2. The preliminary pad patterns may cover the exposed first and second edge portions EA1 and EA2 of the active patterns ACT.

In an embodiment, the preliminary pad pattern may be disposed through an engraving process. For example, the first pad insulating pattern PI1 and the first trench regions TR1 may be formed by etching the first pad insulating layer, and the first pad insulating pattern PI1 may be used as a mold for forming the preliminary pad patterns.

The storage node pad XPS may be formed by etching the preliminary pad patterns. The etching of the preliminary pad patterns may include forming second trench regions TR2 to separate the preliminary pad patterns into the storage node pads XPS. The second trench regions TR2 may extend in the first direction D1. The second trench regions TR2 may cross the first pad insulating pattern PI1 in the first direction D1.

The second pad insulating pattern PI2 may be formed to fill the second trench regions TR2. The second pad insulating patterns PI2 in the second trench regions TR2 may extend in the first direction D1.

Referring to FIGS. 10, 11A, 11B, 11C, and 11D, a buffer layer BF may be formed to cover the substrate 100. In an embodiment, the buffer layer BF may include a lower buffer layer BFa and an upper buffer layer BFb disposed on the lower buffer layer BFa (e.g., in the fourth direction D4).

Thereafter, third trench regions TR3 may be formed by etching the buffer layer BF and the first pad insulating pattern PI1. The third trench regions TR3 may extend in the second direction D2 and may be spaced apart from each other in the third direction D3. The third trench regions TR3 may be formed on the center portions CA of the active patterns ACT. The center portions CA of the active patterns ACT may be exposed through the third trench regions TR3.

The bit line node contact spacers DS may be formed on inner side surfaces of the third trench regions TR3. A bit line contact layer may be formed to fill the third trench regions TR3. In an embodiment, the bit line contact layer may include a first layer, which is formed to cover bottom surfaces of the third trench regions TR3, and a second layer and a third layer, which are sequentially formed on the first layer. In an embodiment, the first layer, the second layer, and the third layer may be formed of or include different materials from each other. For example, the first layer may be formed of or include silicon (e.g., doped polysilicon). The second layer may be formed of or include a silicide material. The third layer may be formed of or include a metallic material. However, embodiments of the present inventive concept are not necessarily limited thereto. A bit line layer and a bit line capping layer may then be sequentially formed on the bit line contact layer.

The bit line capping layer, the bit line layer, and the bit line contact layer may be patterned using a line-shaped mask pattern, which extends in the third direction D3. As a result, the bit line capping pattern 350, the bit line BL, and the bit line node contact DC may be formed. In an embodiment, the bit line capping pattern 350, the bit line BL, and the bit line node contact DC may be formed from the bit line capping layer, the bit line layer, and the bit line contact layer through the etching process. The first, second, and third portions DC1, DC2, and DC3 of the bit line node contact DC may be formed from the first, second, and third layers of the bit line contact layer through the etching process.

Since the bit line node contacts DC are formed by an etching process, a width of the bit line node contacts DC in the second direction D2 may vary depending on a vertical level. For example, in an embodiment a portion of the bit line node contact DC may be over-etched to have the smallest width at a level of the third portion DC3, and the first and second portions DC1 and DC2 may be formed to have an increasing width as a distance (e.g., in the fourth direction D4) to the active pattern ACT decreases. A portion of the buffer layer BF (e.g., the upper buffer layer BFb) may also be partially etched by the etching process.

During the formation of the bit line BL, bit line trench regions BTR may be formed between the bit lines BL. The bit line trench regions BTR may be spaced apart from each other in the second direction D2 and may extend in the third direction D3. Inner surfaces of the third trench regions TR3 may be exposed again through the bit line trench regions BTR.

Referring to FIGS. 12, 13A, 13B, 13C, and 13D, the bit line spacer 360 may be formed on the side surface of the bit line BL. To reduce complexity in the drawings and for ease of description, the first and second pad insulating patterns PI1 and PI2 and the third trench regions TR3 of FIG. 10 may be omitted from FIG. 12. In an embodiment, the formation of the bit line spacer 360 may include sequentially forming the first spacer 362, the second spacer 364, and the third spacer 366 to conformally cover the side surface of the bit line node contact DC, the side surface of the bit line BL, and the bit line capping pattern 350.

The formation of the first spacer 362 may include conformally depositing the first spacer 362 on an inner surface of the bit line trench region BTR and the buffer layer BF and etching the buffer layer BF and the first spacer 362 using the bit line capping pattern 350 as an etch mask. A portion of the buffer layer BF may remain below the bit line capping pattern 350 and may be used as the buffer pattern BF. The etching process on the buffer layer BF may be performed to expose the storage node pads XPS.

The formation of the second and third spacers 364 and 366 may include conformally depositing the second spacer 364 on an inner surface of the bit line trench region BTR and the storage node pads XPS, etching the second spacer 364 on the storage node pads XPS, conformally depositing the third spacer 366 on the second spacer 364 and the storage node pads XPS, and etching the third spacer 366 on the storage node pads XPS. In an embodiment, portions of the second spacers 364 may be formed to be connected to each other between adjacent ones of the bit lines BL. However, embodiments of the present inventive concept are not necessarily limited thereto.

A preliminary filling pattern may be formed to fill lower portions of the bit line trench regions BTR. The preliminary filling pattern may be interposed between adjacent ones of the third spacers 366. The preliminary filling pattern may be formed to have a top surface, which is positioned at a vertical level (e.g., level in the fourth direction D4) that is similar to the vertical level of the top surface of the buffer pattern BF. An etching process on the preliminary filling pattern may be performed to form the filling pattern 370. In an embodiment, when the portions of the second spacers 364, which are adjacent to each other, are formed to be connected to each other, the filling pattern 370 may be disposed between the connection portions of the second spacers 364.

Thereafter, preliminary storage node contacts may be formed to fill remaining portions of the bit line trench regions BTR. The preliminary storage node contacts may be spaced apart from each other in the second direction D2 and may extend in the third direction D3, in the bit line trench regions BTR.

In an embodiment, the formation of the preliminary storage node contacts may include forming a storage node layer to cover inner surfaces of the bit line trench regions BTR and the bit line capping pattern 350 and etching an upper portion of the storage node layer to form the preliminary storage node contacts, which are separated from each other. The etching of the upper portion of the storage node layer may include performing a polishing process on the upper portion of the storage node layer and an upper portion of the bit line capping pattern 350. Thus, a top surface of the preliminary storage node contacts may be substantially coplanar with a top surface of the bit line capping pattern 350 (e.g., in the fourth direction D4).

The storage node contacts BC may be formed in the bit line trench regions BTR. In an embodiment, the formation of the storage node contacts BC may include dividing each of the preliminary storage node contacts into a plurality of the storage node contacts BC through an etching process. Each of the preliminary storage node contacts may be divided into the storage node contacts BC, which are separated from each other, by fence trench regions FTR. The fence trench regions FTR may extend in the second direction D2 and may be spaced apart from each other in the third direction D3.

The preliminary storage node contacts and a portion of the bit line capping pattern 350 may be etched during the etching process. In an embodiment, due to the etch selectivity between the preliminary storage node contacts and the portion of the bit line capping pattern 350, a bottom surface of the fence trench region FTR may be formed to have a groove. For example, the bottom surface of the fence trench region FTR, which is formed between the bit lines BL, may be formed at a level lower than the bottom surface of the fence trench region FTR, which is formed on the bit line capping pattern 350.

One of the fence trench regions FTR may include lower regions, which are linearly arranged in the second direction D2 and between the bit lines BL, and an upper portion of the fence trench region FTR may be connected to the lower portions, on the bit lines BL. In an embodiment, the bottommost surface of the fence trench region FTR may be formed to be lower (e.g., in the fourth direction D4) than the bottommost surface of the storage node contact BC.

The fence patterns FN may then be formed to fill the fence trench regions FTR. In an embodiment, the formation of the fence patterns FN may include forming a fence layer to fill the fence trench regions FTR and cover top surfaces of the storage node contacts BC and removing an upper portion of the fence layer to form the fence patterns FN, which are separated from each other.

Referring back to FIGS. 1, 3A, 3B, 3C, and 3D, an upper portion of the storage node contact BC may be removed. The removal of the upper portion of the storage node contact BC may include performing an etch-back process on the upper portion of the storage node contact BC.

The landing pads LP may be formed on (e.g., formed directly thereon) the storage node contacts BC. In an embodiment, the formation of the landing pads LP may include forming a landing pad layer to cover top surfaces of the storage node contacts BC, forming mask patterns on the landing pad layer, and performing an anisotropic etching process using the mask patterns as an etch mask to divide the landing pad layer into a plurality of landing pads LP.

The insulating pattern 440 may then be formed in a region, which is formed by removing the landing pad layer. The insulating pattern 440 may be formed to enclose each of the landing pads LP. The data storage pattern DSP may be formed on the landing pads LP, respectively. Thus, the semiconductor memory device of FIGS. 1, 3A, 3B, 3C, and 3D may be fabricated.

According to an embodiment of the present inventive concept, elements in a semiconductor memory device may be disposed in a simplified manner. Thus, it may be possible to reduce a process difficulty in a patterning process or the like, which is performed to fabricate a semiconductor memory device. For example, the semiconductor memory device may be more easily fabricated. In addition, since the element are disposed in the simplified manner, an integration density of the semiconductor device may be increased.

While non-limiting embodiments of the present inventive concept have been particularly shown and described, it will be understood by one of ordinary skill in the art that variations in form and detail may be made therein without departing from the spirit and scope of the present inventive concept.

What is claimed is:

1. A semiconductor memory device, comprising:
a first active pattern and a second active pattern that extend in a first direction and are spaced apart from each other in a second direction crossing the first direction, each of the first and second active patterns including a first edge portion and a second edge portion that are spaced apart from each other in the first direction, and a center portion between the first and second edge portions;
bit line node contacts on the center portions of the first and second active patterns; and
bit lines disposed on the bit line node contacts and extending in a third direction crossing the first and second directions,
wherein the center portions of the first and second active patterns are sequentially disposed in the second direction, and
each of the bit line node contacts has a first width at a level of a top surface of the bit line node contacts in direct contact with the bit lines, a second width at a level of a bottom surface of the bit line node contacts in direct contact with the first and second active patterns, and a third width between the top and bottom surfaces of the bit line node contacts, the third width is less than the first and second widths.

2. The semiconductor memory device of claim 1, wherein:
each of the bit line node contacts includes a first portion, a second portion, and a third portion that are sequentially disposed on the first and second active patterns, and
the first, second, and third portions include different materials from each other.

3. The semiconductor memory device of claim 2, wherein:
the third portion of each of the bit line node contacts has the third width; and
widths of the first and second portions increase as a distance to the first and second active patterns decreases.

4. The semiconductor memory device of claim 1, wherein the first width of the top surface of the bit line node contact is less than the second width of the bottom surface.

5. The semiconductor memory device of claim 1, further comprising:
a third active pattern adjacent to the second active pattern in the third direction; and
a fourth active pattern adjacent to the first active pattern in the third direction,
wherein each of the third and fourth active patterns includes a first edge portion and a second edge portion that are spaced apart from each other in the first direction, and a center portion disposed between the first and second edge portions, and
the first edge portion of the first active pattern is adjacent to the second edge portion of the third active pattern in the first direction.

6. The semiconductor memory device of claim 1, wherein the bit lines include recess regions that vertically overlap the bit line node contacts and is recessed towards the bit line node contacts.

7. The semiconductor memory device of claim 1, further comprising:
a substrate having the first and second active patterns disposed thereon; and
a buffer pattern between the substrate and the bit lines,
wherein a top surface of the bit line node contact is positioned at a vertical level that is lower than a top surface of the buffer pattern.

8. The semiconductor memory device of claim 1, wherein:
the bit lines include first portions that vertically overlap with the bit line node contacts, and second portions that are interposed between the first portions;
the first portions have a fourth width; and
the second portions have a fifth width less than the fourth width.

9. The semiconductor memory device of claim 1, further comprising:
a storage node contact disposed between the bit lines and disposed on the first and second edge portions of each of the first and second active patterns; and
a storage node pad interposed between the storage node contact and the first and second active patterns.

10. A semiconductor memory device, comprising:
a device isolation pattern disposed in a substrate, the device isolation pattern defining a plurality of active patterns, the device isolation pattern including first portions extending in a first direction and second portions crossing the first portions and extending in a second direction;
first and second word lines crossing the plurality of active patterns and extending in the second direction;
bit lines disposed on the plurality of active patterns and extending in a third direction crossing the first and second directions; and
bit line node contacts disposed between the plurality of active patterns and the bit lines,
wherein at least a portion of each of the bit line node contacts has an increasing width as a distance to the substrate decreases.

11. The semiconductor memory device of claim 10, wherein:
each of the bit line node contacts includes a first portion, a second portion, and a third portion that are sequentially disposed on the active patterns; and
the first, second, and third portions include different materials from each other.

12. The semiconductor memory device of claim 11, wherein:
the third portion of the bit line node contact has a smallest width; and
widths of the first and second portions increase as a distance to the substrate decreases.

13. The semiconductor memory device of claim 10, wherein:
the first portion includes polysilicon;
the second portion includes silicide; and
the third portion includes a metallic material.

14. The semiconductor memory device of claim 10, further comprising a buffer pattern between the substrate and the bit lines,
wherein top surfaces of the bit line node contacts are positioned at a vertical level that is lower than a top surface of the buffer pattern.

15. The semiconductor memory device of claim 14, wherein:
the bit lines include first portions that vertically overlap the bit line node contacts, and second portions that vertically overlap the buffer pattern; and
a first distance in the second direction between adjacent first portions of the first portions is less than a second distance in the second direction between adjacent second portions of the second portions.

16. A semiconductor memory device, comprising:
a substrate comprising a first active pattern and a second active pattern that extend in a first direction and are spaced apart from each other in a second direction crossing the first direction, each of the first and second active patterns including two edge portions that are spaced apart from each other in the first direction, and a center portion that is interposed between the edge portions,
a pair of word lines extending in the second direction to cross the first and second active patterns;
a storage node pad and a storage node contact that are sequentially disposed on the edge portions;
bit lines that are respectively disposed on the first and second active patterns and extend in a third direction crossing the first and second directions;
a bit line spacer covering side surfaces of the bit lines;
a bit line node contact interposed between the center portion of each of the first and second active patterns and the bit line;
a landing pad on the storage node contact; and
a data storage pattern on the landing pad,
wherein the center portions of the first and second active patterns are sequentially disposed in the second direction,
the bit line node contact has a smallest width at a first level between a top surface of the bit line node contact and a bottom surface of the bit line node contact, and
a width of the bit line node contact decreases from the top surface of the bit line node contact to the first level and then increases from the first level to the bottom surface of the bit line node contact.

17. The semiconductor memory device of claim 16, wherein:
each of the bit line node contacts includes a first portion, a second portion, and a third portion that are sequentially disposed on the first and second active patterns; and
the first, second, and third portions include different materials from each other.

18. The semiconductor memory device of claim 17, wherein the third portion of the bit line node contact is positioned at the first level.

19. The semiconductor memory device of claim 16, further comprising:
a third active pattern adjacent to the second active pattern in the third direction; and
a fourth active pattern adjacent to the first active pattern in the third direction,
wherein each of the third and fourth active patterns includes a first edge portion and a second edge portion that are spaced apart from each other in the first direction, and a center portion between the first and second edge portions,
the center portions of the third and fourth active patterns are sequentially disposed in the second direction, and
the first edge portion of the first active pattern is adjacent to the second edge portion of the third active pattern in the first direction.

20. The semiconductor memory device of claim 16, wherein each of the bit lines includes a recess region that vertically overlaps the bit line node contact and is recessed towards the bit line node contact.
